(19) United States
(12) Patent Application Publication
(10) Pub. No.: US 2017/0288439 A1
(43) Pub. Date: Oct. 5, 2017

(54) SIGNAL PROCESSING CIRCUIT, COULOMB COUNTER CIRCUIT, AND ELECTRONIC DEVICE

(71) Applicant: ROHM CO., LTD., Ukyo-Ku (JP)

(72) Inventor: Yoichi TAMEGAI, Ukyo-Ku (JP)

(21) Appl. No.: 15/474,250

(22) Filed: Mar. 30, 2017

(30) Foreign Application Priority Data
Apr. 1, 2016 (JP) 2016-074593

(51) Int. Cl. H02J 7/00; G01R 31/36; H03M 3/00

(52) U.S. Cl. CPC H02J 7/0078; H03M 3/468; H03M 3/498; H03M 3/378; G01R 31/3617

(57) ABSTRACT

A signal processing circuit includes: a plurality of A/D conversion units of a plurality of channels, each of plurality of the A/D conversion units including an amplifier configured to amplify an input analog signal and an A/D converter configured to convert an output signal from the amplifier into a digital signal, wherein at least one of operation parameters of the amplifier and the A/D converter is set individually for each of the plurality of channels.

### CROSS-REFERENCE TO RELATED APPLICATION(S)

This application is based upon and claims the benefit of priority from Japanese Patent Application No. 2016-074593, filed on Apr. 1, 2016, the entire contents of which are incorporated herein by reference.

### TECHNICAL FIELD

The present disclosure relates to A/D conversion.

### BACKGROUND

In various electronic devices, an A/D converter for converting an analog signal representing an electrical state of an internal circuit or a physical state of an electronic device into a digital signal is used for digital signal processing of these states.

FIG. 1 is a circuit diagram of a signal processing circuit 100r reviewed by the present inventor. The signal processing circuit 100r includes an amplifier 10, an A/D converter 20, and a digital circuit 30. When an input analog signal S1 to be monitored is small, the amplifier 10 is installed in a front stage of the A/D converter 20. The amplifier 10 amplifies the input analog signal S1 to an appropriate level within an input range of the A/D converter 20, and the A/D converter 20 performs AD conversion on an amplified analog signal S2. The digital circuit 30 processes a digital signal S3 from the A/D converter 20.

As a result of reviewing the signal processing circuit 100r of FIG. 1, the present inventor has recognized the following problems.

The behavior (waveform) of the input analog signal S1 may differ from time to time. For example, the current of a battery mounted on an electronic device is stationary without little variation in an idle state of the electronic device, while it dynamically varies at a high rate when the electronic device is used.

When the gain of the amplifier 10 or the sampling frequency of the A/D converter 20 is designed to be optimized for the behavior of the input analog signal S1 in a certain typical situation, it is difficult to obtain a correct digital value when the behavior of the input analog signal S1 changes.

In order to appropriately convert the input analog signal S1 whose behavior drastically changes into the digital signal S3, it is also considered that an approach of dynamically or adaptively changing the characteristics (operation parameters) of the amplifier 10 and the A/D converter 20 depending on the behavior of the analog signal is employed. However, a certain amount of time is required for changing the operation parameters of the amplifier 10 or the A/D converter 20. Thus, when the operation parameters of the amplifier 10 or the A/D converter 20 change, it is impossible to measure the input analog signal S1 for a while. In particular, when changing the characteristics of the A/D converter, if calibration is performed for each change, an invalid time during which the input analog signal S1 cannot be measured becomes longer.

### SUMMARY

The present disclosure provides some embodiments of a signal processing circuit capable of appropriately measuring an analog signal whose behavior changes.

According to one embodiment of the present disclosure, there is provided a signal processing circuit. The circuit includes: a plurality of A/D conversion units of a plurality of channels, each of the plurality of the A/D conversion units including an amplifier configured to amplify an input analog signal and an A/D converter configured to convert an output signal from the amplifier into a digital signal. At least one of a plurality of operation parameters of the amplifier and the A/D converter is set individually for each of the plurality of channels.

According to the present embodiment, the operation parameters and characteristics of the A/D conversion units are set on the assumption of a variation in behavior or waveform of the input analog signal, and one suitable for the current state of the input analog signal among the plurality of channels is selected. Thus, it is possible to properly measure the analog signal.

The A/D converter may be a ΔΣ type A/D converter. The ΔΣ type A/D converter requires a long period of time for a single measurement, compared with a successive approximation A/D converter, thus requiring a long period of time to change the operation parameters. Thus, the effects of the present disclosure can be further beneficial to the signal processing circuit having the ΔΣ type A/D converter.

A sampling rate and filter characteristics of the A/D converter may be variable. A gain of the amplifier may be variable.

The plurality of A/D conversion units of the plurality of channels may include a first A/D conversion unit configured to sample a wide dynamic range at a high rate and a second A/D conversion unit configured to sample a narrow dynamic range at a low rate with high accuracy.

The signal processing circuit may further include a digital circuit configured to perform signal processing on the digital signal. The digital circuit may validate one the plurality of A/D conversion units of the plurality of channels depending on a state of the input analog signal, and process a digital signal from the validated A/D conversion unit from the plurality of A/D conversion units.

The digital circuit may validate plural ones of the plurality of the A/D conversion units of the plurality of channels depending on a state of the input analog signal, and process an optimal one among digital signals from the validated ones of the plurality of A/D conversion units.

The signal processing circuit may further include an abnormality detection part configured to generate a plurality of digital signals by the plurality of A/D conversion units of the plurality of channels in a state in which the input analog signal is fixed and determine whether each of the plurality of channels has an abnormality based on the plurality of digital signals.

The signal processing circuit may be integrated on a single semiconductor substrate.

According to another embodiment of the present disclosure, there is provided a coulomb counter circuit. The circuit may include: an input terminal configured to receive a current sensing signal representing a current flowing in a battery; the signal processing circuits described above, configured to covert the current detection signal into a digital signal; and a calculation part configured to integrate an output signal from the signal processing circuit.

According to yet another embodiment of the present disclosure, there is provided an electronic device. The electric device may include: a battery; a charging circuit configured to charge the battery; the coulomb counter circuit described above, configured to detect charging or discharging electric charge of the battery; and a residual amount detection circuit configured to detect a residual amount of the battery based on an output of the coulomb counter circuit.

Further, arbitrarily combining the foregoing components or substituting the components or expressions of the present disclosure with one another among a method, an apparatus, and a system is also effective as an embodiment of the present disclosure.

### BRIEF DESCRIPTION OF THE DRAWINGS

FIG. 1 is a circuit diagram of a signal processing circuit reviewed by the present inventor.

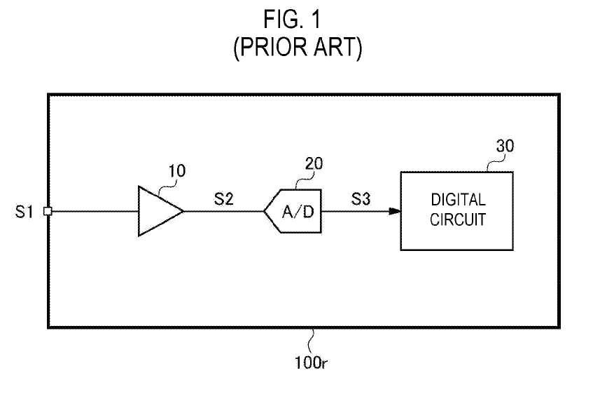

FIG. 2 is a block diagram of a signal processing circuit according to an embodiment of the present disclosure.

FIG. 3 is an operational waveform diagram of the signal processing circuit of FIG. 2.

FIG. 4 is a block diagram of an electronic device including a signal processing circuit.

FIG. 5 is a block diagram of an electronic device including a signal processing circuit.

### DETAILED DESCRIPTION

Embodiments of the present disclosure will be now described in detail with reference to the drawings. Like or equivalent components, members, and processes illustrated in each drawing are given like reference numerals and a repeated description thereof will be properly omitted. Further, the embodiments are presented by way of example only, and are not intended to limit the present disclosure, and any feature or combination thereof described in the embodiments may not necessarily be essential to the present disclosure.

In the present disclosure, “a state where a member A is connected to a member B” includes a case where the member A and the member B are physically directly connected or even a case where the member A and the member B are indirectly connected through any other member that does not affect an electrical connection state between the members A and B or does not impair functions and effects achieved by combinations of the members A and B. Similarly, “a state where a member C is installed between a member A and a member B” includes a case where the member A and the member C or the member B and the member C are indirectly connected through any other member that does not affect an electrical connection state between the members A and C or the members B and C or does not impair function and effects achieved by combinations of the members A and C or the members B and C, in addition to a case where the member A and the member C or the member B and the member C are directly connected.

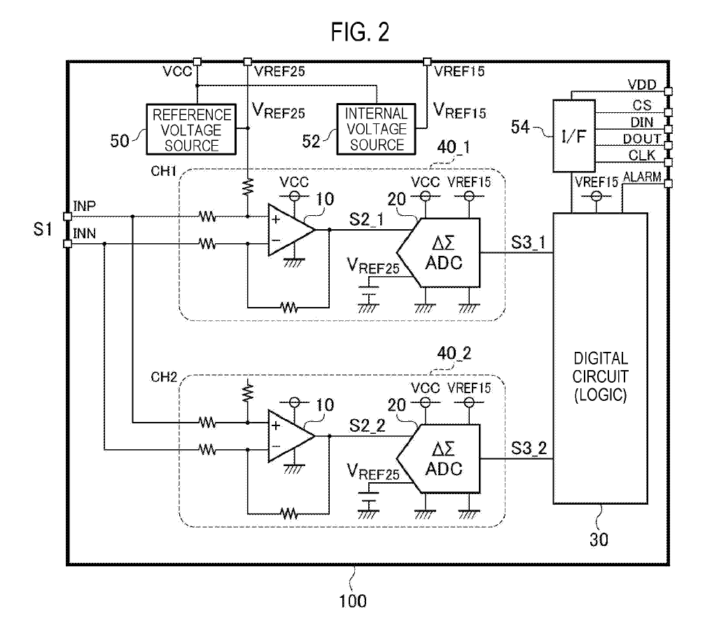

FIG. 2 is a block diagram of a signal processing circuit 100 according to an embodiment of the present disclosure. The signal processing circuit 100 converts an input analog signal S1 corresponding to a potential difference between input terminals INP and INN into a digital signal, and performs predetermined signal processing. The signal processing circuit 100 may be a functional IC integrated on a single semiconductor substrate. The signal processing circuit 100 includes A/D conversion units 40_1 to 40_n of a plurality of channels CH1 to CHn. In this embodiment, the case of n=2 will be described for simplicity of explanation and facilitation of understanding, but n may be any integer of three or more. Hereinafter, when it is unnecessary to distinguish the channels, the subscripts (_1, _2, . . . ) indicating the channel numbers 1, 2, . . . , of each signal will be properly omitted.

A source voltage for an analog circuit block is supplied to a power supply terminal VCC from the outside. The common input analog signal S1 is input to each A/D conversion unit 40. The A/D conversion unit 40_i (where i=1, 2, . . . ) includes an amplifier 10 for amplifying the input analog signal S1 and an A/D converter 20 for converting an output signal S2_i from the amplifier 10 into a digital signal S3_i.

The A/D conversion units 40_1 to 40_n of the plurality of channels have the same configuration, and at least one of the operation parameters of the amplifier 10 and the A/D converter 20 may be set individually for each channel For example, a gain of the amplifier 10, a sampling rate of the A/D converter 20, filter characteristics, and the like may be set individually for each channel

The A/D converter 20 may be a ΔΣ type A/D converter. Each A/D converter 20 is variable in sampling rate and filter characteristics.

A reference voltage source 50 and an internal voltage source 52 generate reference voltages V_{REF25} and V_{REF15} having different voltage levels, respectively. The amplifier 10 may be a non-inverting differential amplifier and amplifies the input analog signal S1 with respect to the reference voltage V_{REF25} to generate the analog signal S2. The A/D converter 20 converts the analog signal S2 into the digital signal S3 using the reference voltages V_{REF25} and V_{REF15}. The reference voltage terminal VREF25 and the internal voltage terminal VREF15 are respectively connected to outputs of the reference voltage source 50 and the internal voltage source 52 so as to be connected to an external smoothing capacitor. In addition, the reference voltage V_{REF25} and the internal voltage V_{REF15} may be referred to from an external circuit of the signal processing circuit 100.

Digital signals S3_1 and S3_2 generated by the A/D conversion units 40_1 and 40_2 are input to a digital circuit 30. The digital circuit 30 performs predetermined signal processing on the digital signals S3_1 and S3_2. The digital circuit 30 is connected to an external processor via an interface circuit 54 to transmit data after signal processing. The interface circuit 54 may be, for example, a serial peripheral interface (SPI) or an inter IC (I²C) interface. The content of signal processing performed by the digital circuit 30 is not particularly limited. A source voltage to a digital circuit block is supplied to a power supply terminal VDD. DIN denotes a data input terminal, DOUT denotes a data output terminal, CS denotes a chip select terminal, and CLK denotes an input terminal of a serial clock. Further, when the digital circuit 30 detects a certain abnormality, it controls an electrical state of an alarm terminal ALARM and notifies an external circuit about the same.

The operation parameters and characteristics of the A/D conversion unit 40_1 and A/D conversion unit 40_2 are set on the assumption of a variation in behavior and waveform of the input analog signal S1. The operation parameters of the A/D conversion units 40 of the plurality of channels are set up when the signal processing circuit 100 starts up, and fixed after the operation starts.

A setting example of the operation parameters of the A/D conversion units 40 of the plurality of channels will be described in association with a behavior of the input analog signal S1.

A signal level (i.e., strength or amount) of the input analog signal S1 greatly changes depending on a situation. In this case, for example, the operation parameters of the first A/D conversion unit 40_1 are set to sample a wide dynamic range at a high rate. Specifically, a gain of the amplifier 10 is set to be relatively low, a sampling frequency of the A/D converter 20 is set to be relatively high, and an internal filter coefficient is set to have a relatively wide band.

On the other hand, the operation parameters of the second A/D conversion unit 40_2 are set to sample a narrow dynamic range at a low rate with high accuracy. Specifically, a gain of the amplifier 10 is set to be relatively high, a sampling frequency of the A/D converter 20 is set to be relatively low, and an internal filter coefficient is set to have a relatively narrow band.

According to the first A/D conversion unit 40_1, it is possible to accurately measure the input analog signal S1 having a large value. On the other hand, according to the second A/D conversion unit 40_2, it is possible to accurately measure the input analog signal S1 having a small value. Here, since the A/D converter 20 has a lower noise as the sampling frequency is lower, the detection accuracy of the input analog signal S1 having a small value is further improved using the second A/D conversion unit 40_2.

The digital circuit 30 estimates or detects a behavior or waveform of the current input analog signal S1 from the history of the past digital signals S3_1 and S3_2. Based on the estimation or detection result, the digital circuit 30 validates one of the plurality of channels which is suitable for the state of the current input analog signal S1, and processes the digital signal S3 from the A/D conversion unit 40 of the validated channel. That is, the digital circuit 30 validates one A/D conversion unit 40 and processes a digital signal S3 from the validated A/D conversion unit 40.

The digital circuit 30 may operate only the A/D conversion unit 40 of the validated channel, and stop the A/D conversion units 40 of the remaining channels. Thus, it is possible to reduce power consumption.

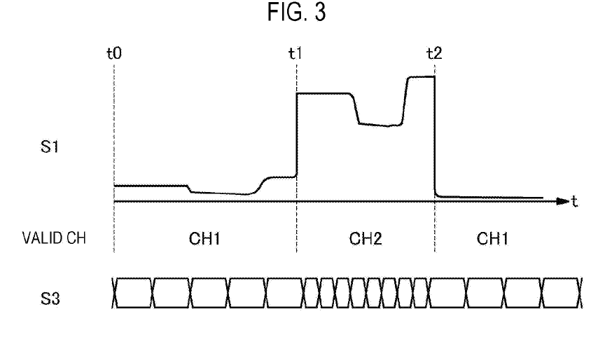

The foregoing is the configuration of the signal processing circuit 100. Next, an operation of the signal processing circuit 100 will be described. FIG. 3 is an operational waveform diagram of the signal processing circuit 100 of FIG. 2. The vertical axis and the horizontal axis of the waveform diagram or the time chart referred to herein are appropriately expanded and reduced for easy understanding, and each waveform shown is also simplified, exaggerated, or emphasized for easy understanding.

During a time period of t0 to t1, the signal level of the input analog signal S1 is small and a first channel CH1 is validated. The digital signal S3 is generated at a relatively low sampling rate.

During a time period of t1 to t2, the signal level of the input analog signal S1 increases and a second channel CH2 is validated. The digital signal S3 is generated at a relatively high sampling rate.

At time t2, the signal level of the input analog signal S1 again decreases and the first channel CH1 is validated.

The foregoing is the operation of the signal processing circuit 100. According to this signal processing circuit 100, the plurality of A/D conversion units 40 are prepared and swichably used depending on a behavior of the input analog signal S1 so as to accurately measure the input analog signal S1.

In particular, compared with a successive approximation A/D converter or the like, the ΔΣ type A/D converter 20 requires a long period of time for a single measurement, thus requiring a long period of time to change the operation parameters. Thus, the effects of the present disclosure may be further beneficial to the signal processing circuit 100 having the ΔΣ type A/D converter 20.

The present disclosure has been described above based on the embodiment. It is to be understood by those skilled in the art that the embodiment is merely illustrative and may be differently modified by any combination of the components or processes, and the modifications are also within the scope of the present disclosure. Hereinafter, these modifications will be described.

### First Modification

In the embodiment, there has been described a case where the gain of the amplifier 10, the sampling rate of the A/D converter 20, and the filter characteristics are different for each channel, but the present disclosure is not limited thereto. In a case where a variation in the signal level of the input analog signal S1 is not so large and its variation rate changes depending on a situation, only the operation parameters of the A/D converter 20 may be different for each channel.

### Second Modification

In the embodiment, one of the plurality of channels is operated and the remaining channels are stopped, but the present disclosure is not limited thereto. For example, a plurality of digital signals S3 are generated in advance by operating the A/D conversion units 40 of the plurality of channels, and an optimal digital signal S3 may be selected by the digital circuit 30.

### Third Modification

When the input analog signal S1 is a current signal, the amplifier 10 may be configured as a transformer impedance amplifier.

### Fourth Modification

When the number of channels is three or more, the operation parameters of the amplifier 10 and the A/D converter 20 may be more variously changed for each channel

### Fifth Modification

In the embodiment, the operation parameters of the A/D conversion units 40 of the plurality of channels are set when the signal processing circuit 100 starts up, but the present disclosure is not limited thereto. For example, when the operation parameters necessary for each channel are known in the design stage of the signal processing circuit 10, the operation parameters of the plurality of A/D conversion units 40 may be designed differently in the manufacturing stage.

### Sixth Modification

The signal processing circuit 100 of FIG. 2 has two input terminals INP and INN, but it may receive a single-end input analog signal S1 with respect to a ground voltage.

### Seventh Modification

The digital circuit 30 may include an abnormality detection part. The abnormality detection part may generate the plurality of digital signals S3 by the A/D conversion units 40 of the plurality of channels in a state in which the input analog signal S1 is fixed, and determine whether each channel has an abnormality based on a comparison result of the plurality of digital signals S3. Thus, it is possible to detect a failure or an abnormality even during the operation of the signal processing circuit 100.

### Applications

Next, applications of the signal processing circuit 100 will be described. The signal processing circuit 100 is suitable for an application of sensing an electrical state or a physical state in which a time scale of variation dynamically changes. Such an application may be detecting a residual amount of battery.

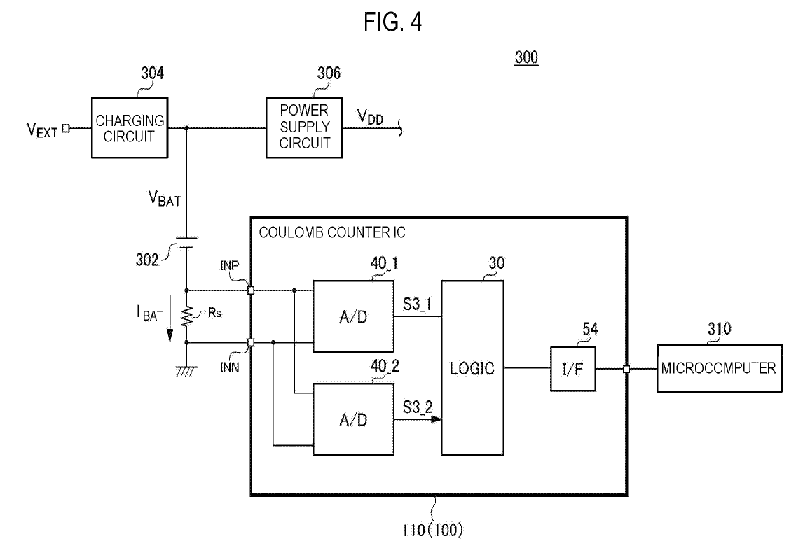

FIG. 4 is a block diagram of an electronic device 300 including the signal processing circuit 100. Specifically, the signal processing circuit 100 may be used in a coulomb counter circuit 110. The coulomb counter circuit 110 is mounted on the battery-driven electronic device 300. The electronic device 300 includes a battery 302, a charging circuit 304, and a power supply circuit 306, in addition to the coulomb counter circuit 110.

The charging circuit 304 receives a voltage V_{EXT} from the outside and charges the battery 302. The power supply circuit 306 receives a battery voltage V_{BAT} or the voltage V_{EXT} from the outside, steps up or steps down the same, and supplies a source voltage V_{DD} to a load (not shown). A current sensor is installed to measure a current I_{BAT} flowing in the battery 302. The current sensor may be configured as, for example, a sense resistor R_{S} installed in series with the battery 302, and a voltage drop in the sense resistor Rs is input to the coulomb counter circuit 110 as the input analog signal S1 representing a current amount.

The coulomb counter circuit 110 is used for detecting a residual amount of the battery by a coulomb counting method, and generates at least one of a charge coulomb count (CCC) of the battery, a discharge coulomb count (DCC) of the battery, and an accumulate coulomb count (ACC). The digital circuit 30 includes a computing element for integrating the digital signal S3. For example, the digital circuit 30 may integrate the digital signal S3_1 or S3_2 corresponding to a positive current I_{BAT} so as to generate a CCC value. Further, the digital circuit 30 may integrate the digital signal S3_1 or S3_2 corresponding to a negative current I_{BAT} so as to generate a DCC value. Furthermore, the digital circuit 30 may integrate the digital signal S3_1 or S3_2, regardless of the positive or negative current, so as to generate an ACC value.

The coulomb count value generated by the digital circuit 30 is transmitted to a microcomputer 310 via the interface circuit 54. The microcomputer 310 calculates a residual amount of the battery 302 based on the coulomb count value.

A change rate or an amount of the battery current I_{BAT} varies largely depending on an operational state of the electronic device 300. The measurement of the battery current I_{BAT} having such properties is suitable for the application of the signal processing circuit 100.

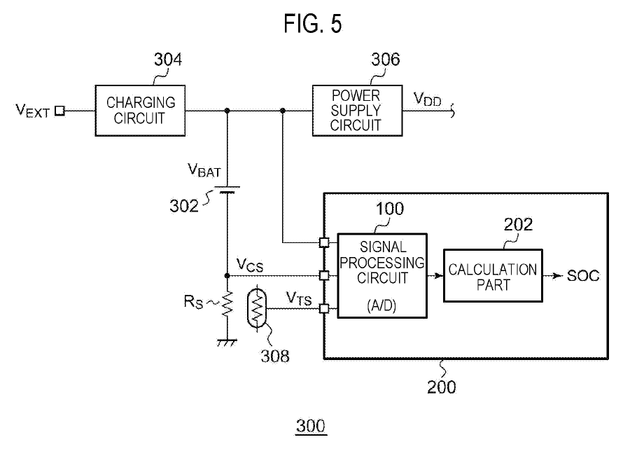

FIG. 5 is a block diagram of the electronic device 300 including the signal processing circuit 100. The signal processing circuit 100 may be used in a battery residual amount detection circuit 200. The battery residual amount detection circuit 200 detects a state of charge (SOC) of the battery 302. For example, the battery voltage V_{BAT}, a current sensing signal V_{CS} representing a charge/discharge current of the battery 302, and a temperature sensing signal V_{TS} representing a temperature of the battery 302 are input to the battery residual amount detection circuit 200. The current sensing signal V_{CS} is, for example, a voltage drop in the sense resistor R_{S} installed in series with the battery 302. The temperature sensing signal V_{TS} is generated by a temperature sensor 308 such as a thermistor, a thermocouple or the like. The battery residual amount detection circuit 200 has the signal processing circuit 100 described above. The signal processing circuit 100 receives the battery voltage V_{BAT}, the current sensing signal V_{CS}, and the temperature sensing signal V_{TS}, and converts them into digital values.

A calculation part 202 estimates a residual amount of the battery 302 based on the battery voltage, the current value, and the temperature measured by the signal processing circuit 100. There are various methods for estimating the residual amount of the battery 302. For example, a method based on an open circuit voltage (OCV) measured in a load-free state of the battery, a coulomb counting method of integrating a charge/discharge current, or the like may be used.

A change rate of the battery current I_{BAT} or battery voltage V_{BAT} varies depending on a state of the electronic device 300. For example, in a case where the electronic device 300 is a communication terminal, when the electronic device 300 is in operation with a heavy load or in the course of quick charging, the battery voltage V_{BAT} changes at a short time scale. Conversely, when the electronic device 300 is not in use, i.e., in a sleep state, a change rate of the battery voltage V_{BAT} is very low. Further, a time scale of variation in temperature dynamically changes.

Thus, the signal processing circuit 100 may be suitably used in measuring a battery voltage, a temperature, and a battery current.

According to some embodiments of the present disclosure, it is possible to appropriately measure an analog signal whose behavior changes.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A signal processing circuit, comprising:
a plurality of A/D conversion units of a plurality of channels, each of the plurality of the A/D conversion units including an amplifier configured to amplify an input analog signal and an A/D converter configured to convert an output signal from the amplifier into a digital signal,
wherein at least one of a plurality of operation parameters of the amplifier and the A/D converter is set individually for each of the plurality of channels.

2. The signal processing circuit of claim 1, wherein the A/D converter is a ΔΣ type A/D converter.

3. The signal processing circuit of claim 2, wherein a sampling rate and filter characteristics of the A/D converter are variable.

4. The signal processing circuit of claim 1, wherein a gain of the amplifier is variable.

5. The signal processing circuit of claim 1, wherein the plurality of A/D conversion units of the plurality of channels includes a first A/D conversion unit configured to sample a wide dynamic range at a high rate and a second A/D conversion unit configured to sample a narrow dynamic range at a low rate with high accuracy.

6. The signal processing circuit of claim 1, further comprising:
a digital circuit configured to perform signal processing on the digital signal,
wherein the digital circuit validates one of the plurality of A/D conversion units of the plurality of channels depending on a state of the input analog signal, and processes a digital signal from the validated A/D conversion unit from the plurality of A/D conversion units.

7. The signal processing circuit of claim 1, further comprising:
a digital circuit configured to perform signal processing on the digital signal,
wherein the digital circuit validates plural ones of the plurality of the A/D conversion units of the plurality of channels depending on a state of the input analog signal, and processes an optimal one among digital signals from the validated ones of the plurality of A/D conversion units.

8. The signal processing circuit of claim 1, further comprising an abnormality detection part configured to generate a plurality of digital signals by the plurality of A/D conversion units of the plurality of channels in a state in which the input analog signal is fixed and determine whether each of the plurality of channels has an abnormality based on the plurality of digital signals.

9. The signal processing circuit of claim 1, wherein the signal processing circuit is integrated on a single semiconductor substrate.

10. A coulomb counter circuit, comprising:
an input terminal configured to receive a current sensing signal representing a current flowing in a battery;
the signal processing circuit of claim 1, configured to covert the current sensing signal into a digital signal; and
a calculation part configured to integrate an output signal from the signal processing circuit.

11. An electronic device, comprising:
a battery;
a charging circuit configured to charge the battery;
the coulomb counter circuit of claim 10, configured to detect charging or discharging electric charge of the battery; and
a residual amount detection circuit configured to detect a residual amount of the battery based on an output of the coulomb counter circuit.
